(19) United States
(12) Patent Application Publication
(10) Pub. No.: US 2025/0141406 A1
(43) Pub. Date: May 1, 2025

(54) INDUCTOR REUSE TECHNIQUE FOR AMPLIFIER

(71) Applicant: QUALCOMM Incorporated, San Diego, CA (US)

(72) Inventors: Xingyi HUA, San Diego, CA (US); Hsiao-Tsung YEN, San Diego, CA (US); Mehmet UZUNKOL, San Diego, CA (US)

(21) Appl. No.: 18/499,682

(22) Filed: Nov. 1, 2023

(51) Int. Cl. H03F 1/22; H03F 1/56; H03F 3/72

(52) U.S. Cl. CPC H03F 1/223; H03F 1/565; H03F 3/72; H03F 2200/294; H03F 2203/7239

(57) ABSTRACT

Certain aspects of the present disclosure provide an amplifier. The amplifier generally includes: an active path coupled between an input node of the amplifier and an output node of the amplifier, wherein the active path comprises a first transistor coupled to the input node of the amplifier and a first inductive element coupled between the first transistor and the output node; and a bypass path coupled between the input node of the amplifier and the output node of the amplifier, the bypass path also comprising the first inductive element.

### TECHNICAL FIELD

Certain aspects of the present disclosure generally relate to electronic circuits and, more particularly, to techniques and apparatus for signal amplification.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, 5G New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more amplifiers. For example, the base station or mobile station may include a low-noise amplifier (LNA) amplifying a signal received via one or more antennas.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include reduced area consumption and cost of an amplifier.

Certain aspects of the present disclosure provide an amplifier. The amplifier generally includes: an active path coupled between an input node of the amplifier and an output node of the amplifier, wherein the active path comprises a first transistor coupled to the input node of the amplifier and a first inductive element coupled between the first transistor and the output node; and a bypass path coupled between the input node of the amplifier and the output node of the amplifier, the bypass path comprising the first inductive element.

Certain aspects of the present disclosure provide a method for signal amplification. The method generally includes: receiving, at an input node of an amplifier, a signal for amplification via the amplifier; amplifying, via an active path of the amplifier coupled between the input node and an output node of the amplifier, wherein the active path comprises a first transistor coupled to the input node of the amplifier and a first inductive element coupled between the first transistor and the output node; and activating a bypass path of the amplifier coupled between the input node and the output node, the bypass path comprising the first inductive element.

Certain aspects of the present disclosure provide a wireless device. The wireless device generally includes one or more antennas and a low-noise amplifier (LNA) having an input node coupled to the one or more antennas, the LNA comprising: an active path coupled between the input node of the LNA and an output node of the LNA, wherein the active path comprises a transistor coupled to the input node and an inductive element coupled between the transistor and the output node; and a bypass path coupled between the input node and the output node, the bypass path comprising the inductive element.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 illustrates an example low-noise amplifier (LNA).

FIG. 5 illustrates an example LNA with at least a portion of active and bypass paths of the LNA being shared, in accordance with certain aspects of the present disclosure.

FIG. 6 illustrates an example LNA including a bypass path inductive element magnetically coupled with an active path inductive element, in accordance with certain aspects of the present disclosure.

FIGS. 7A and 7B illustrate an inductive element structure used to implement inductive elements, in accordance with certain aspects of the present disclosure.

FIG. 8 illustrates an inductive element structure implemented on two layers of an integrated circuit (IC), in accordance with certain aspects of the present disclosure.

FIG. 9 is a flow diagram of example operations for signal amplification, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards an amplifier having an active path for signal amplification and a bypass path for bypassing the amplifier. Certain aspects are directed towards sharing an inductive element between the active and bypass paths, allowing the area consumption and cost of the amplifier to be reduced. In some aspects, an inductive element of the bypass path may be magnetically coupled with inductive elements of the active path, allowing for further reduction in the bypass path inductive element. The inductive elements of the active and bypass paths may be implemented using an inductive element structure on two layers of an integrated circuit (IC). In some aspects, the amplifier may be a low-noise amplifier (LNA). The present disclosure provides an LNA design where the inductive elements for the active LNA path (e.g., providing amplification gain) and the bypass path are merged into a single integrated inductor structure. Tuning capacitive elements may also be shared for the active and bypass paths. The inductive element structure saves area by providing an integrated structure for the bypass and active paths while maintaining performance over other LNA implementations.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

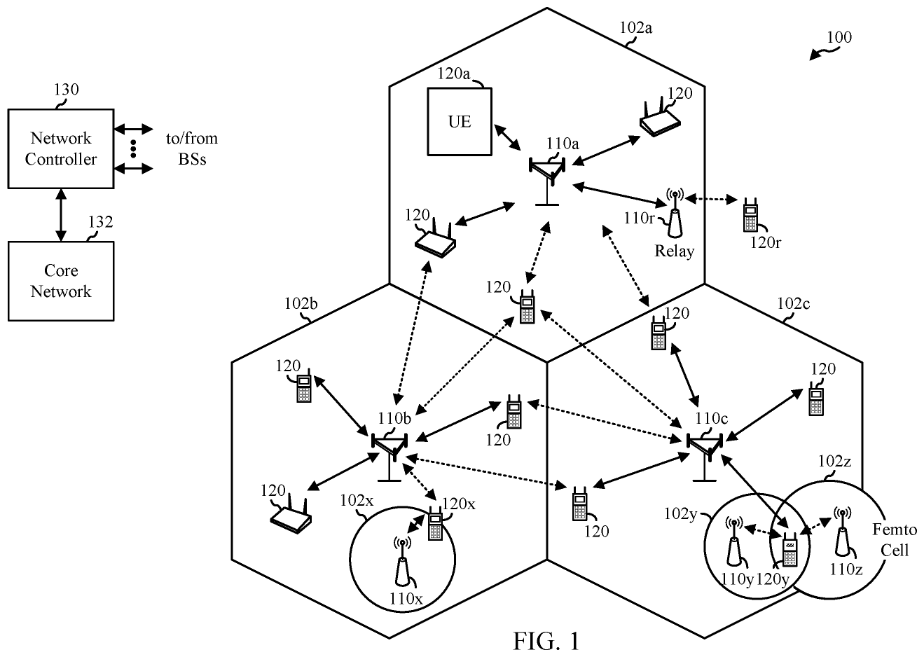

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nup UEs may be selected for simultaneous transmission on the uplink, Nan UEs may be selected for simultaneous transmission on the downlink. Nup may or may not be equal to Nan, and Nup and Nan may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nap of antennas to achieve transmit diversity for downlink transmissions and/or receive diversity for uplink transmissions. A set Nu of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nu UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a low-noise amplifier (LNA) implemented with active and bypass paths sharing an inductive element, as described in more detail herein.

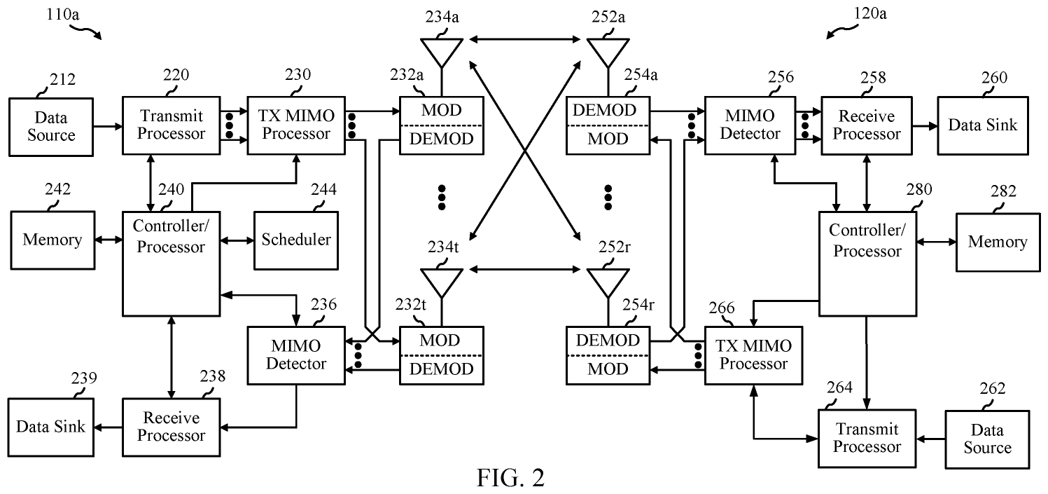

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

In certain aspects of the present disclosure, the transceivers 232 and/or the transceivers 254 may include a low-noise amplifier (LNA) implemented with active and bypass paths sharing an inductive element, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

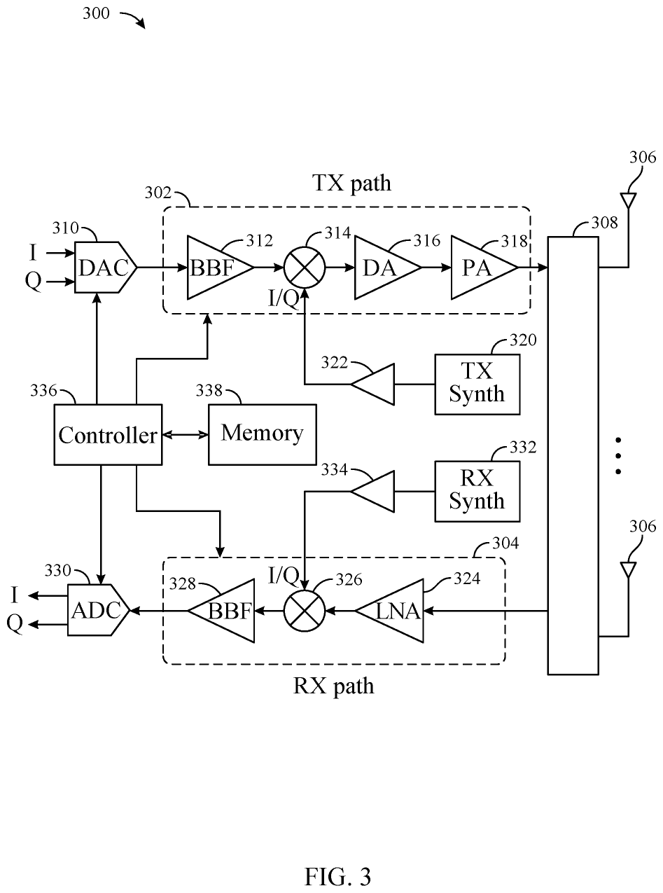

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. In some aspects, the LNA 324 may be implemented with active and bypass paths sharing an inductive element, as described in more detail herein. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for any of various other suitable systems (e.g., an amplifier or other electronic system).

### Example Low-Noise Amplifier (LNA)

For radio frequency integrated circuit (RFIC) design, an on-chip inductive element may be used to implement impedance matching for a low-noise amplifier (LNA). The on-chip inductive element may consume a large area. A multi-gain-mode LNA may have one inductor for impedance matching for an active path of the LNA, and one for impedance matching for a bypass path of the LNA. Either the active path of the LNA may be active for amplification, or the LNA may be bypassed by activating the bypass path. Thus, the two inductive elements for the active and bypass paths may not be on at the same time. Certain aspects of the present disclosure are directed towards using the same inductive element for both the bypass and active paths, reducing the number of on-chip inductive elements for the LNA, saving on area and cost. Certain aspects provide a circuit topology for a multi-gain-mode LNA and coil topology for a high coupling (e.g., high coupling factor K), high quality factor (Q), and two-tap inductive element.

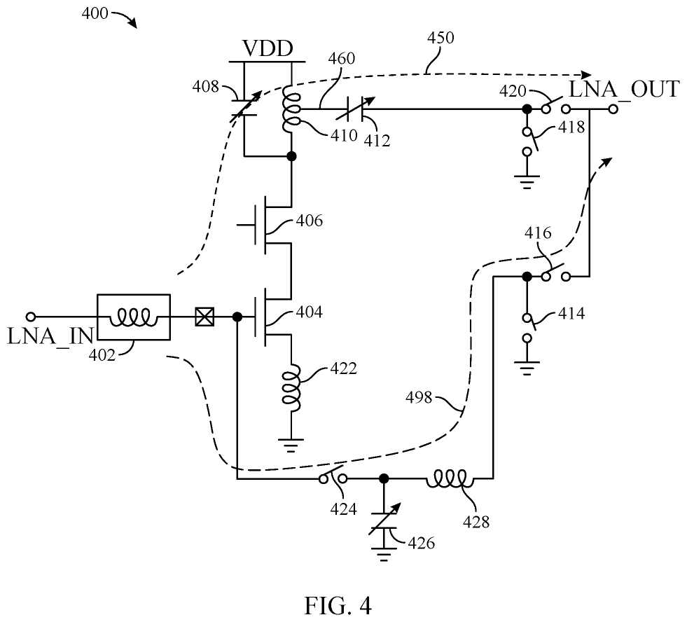

FIG. 4 illustrates an LNA 400 having an inductive element 402 (e.g., an off-chip surface mount device (SMD) inductor) coupled between an input node (e.g., labeled “LNA_IN”) and a gate of transistor 404. As shown, the source of transistor 404 may be coupled to a reference potential node (e.g., electric ground) through an inductive element 422. The drain of transistor 404 may be coupled to a source of transistor 406. The transistor 406 may be biased using a bias voltage when the LNA 400 is active.

A drain of transistor 406 may be coupled to an active path impedance matching circuit having an inductive element 410 in parallel with a variable capacitive element 408. As shown, each of the inductive element 410 and the capacitive element 408 are coupled between a supply voltage (VDD) node and the transistor 406. As shown, a tap (e.g., center tap) of the inductive element 410 may be coupled to a first terminal of an alternating current (AC) coupling capacitive element 412 (e.g., a variable capacitive element). A second terminal of the capacitive element 412 may be selectively coupled to an output node of the LNA (labeled “LNA_out”) through a switch 420. The switch 420 may be closed when the active LNA path 450 is enabled and may be open when the active LNA path 450 is disabled. A switch 418 may be coupled between the second terminal of the capacitive element 412 and a reference potential node (e.g., electric ground). The switch 418 may be closed when switch 420 is open.

The LNA 400 also includes a bypass path 498 implemented via a switch 424 coupled between a gate of transistor 404 and a bypass path impedance matching circuit with an inductive element 428 and a variable capacitive element 426. As shown, the capacitive element 426 may be coupled in shunt between the switch 424 and the reference potential node (e.g., electric ground), and the inductive element 428 may be coupled in series between the switch 424 and a switch 416. As shown, a switch 414 may be coupled in shunt between the inductive element 428 and the reference potential node (electric ground). The switch 416 selectively coupled to the inductive element 428 to the output node (labeled “LNA_OUT”) of the LNA 400, as shown. The switches 416, 424 may be closed when the LNA is in bypass mode. The switches 416, 424 may be opened, and the switch 414 may be closed, when the active LNA path 450 is enabled.

As described, either the active path of the LNA may be active for amplification, or the LNA may be bypassed by activating the bypass path. In certain aspects of the present disclosure, at least a portion of the active and bypass paths may be shared, reducing area consumption and cost of the LNA. In some aspects, instead of using two separate inductive elements 410, 428 for the respective active and bypass paths, the same inductive element may be used, reducing the area consumption and cost of the LNA. In some aspects, a gain of the LNA may be adjusted by adjusting a resistive element (not shown) which may be coupled in parallel with inductive element 410.

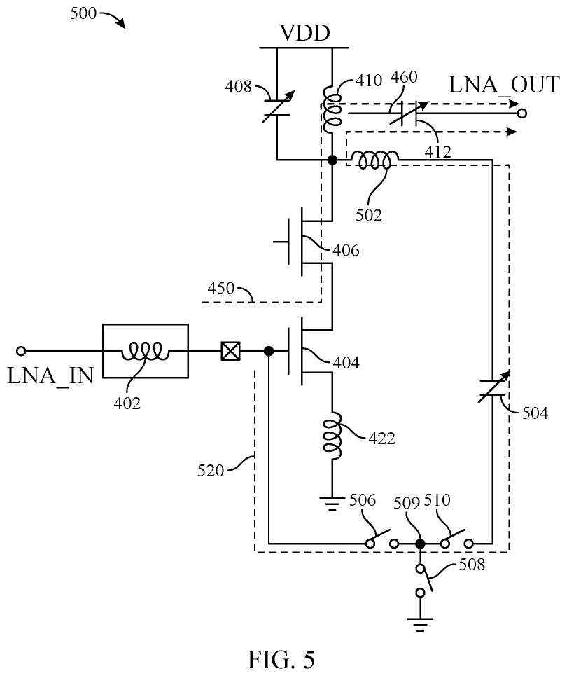

FIG. 5 illustrates an LNA 500 with at least a portion of active and bypass paths of the LNA being shared, in accordance with certain aspects of the present disclosure. As shown, the bypass path 520 may include series switches 506, 510 coupled between the gate of transistor 404 and the variable capacitive element 504. The bypass path 520 may also include an inductive element 502 that may be coupled between the capacitive element 504 and the inductive element 410. During a bypass mode, switches 506, 510 are closed. A switch 508 may be coupled in shunt between the reference potential node (electric ground) and the node 509 between the switches 506, 510. The switch 508 may be closed in active mode (e.g., when switches 506, 510 are open to ground the node 509 between the switches 506, 510). As shown, the bypass path 520 may be from the gate transistor 404, across capacitive element 504, across inductive element 502, across a portion of the inductive element 410 to the tap 460, and across the capacitive element 412 to the output node. Thus, a portion of the bypass path 520 may be shared with the active path 450 (e.g., a portion of inductive element 410 is shared by the active and bypass paths). The capacitive element 504 serves as a direct-current (DC) blocking capacitive element. In bypass mode, the LNA input node may be at zero volts. With respect to DC, the inductive elements 502, 410 act as short circuits. Thus, without the capacitive element 504 to block DC, the LNA input node (e.g., at zero volts) would be coupled to the supply voltage VDD.

As compared to LNA 400, the LNA 500 uses fewer switches and does not use the bypass capacitive element 426. Although LNA 500 includes the capacitive element 504, the capacitive element 504 may be smaller than capacitive element 426. Thus, the LNA 500 has a smaller size than LNA 400.

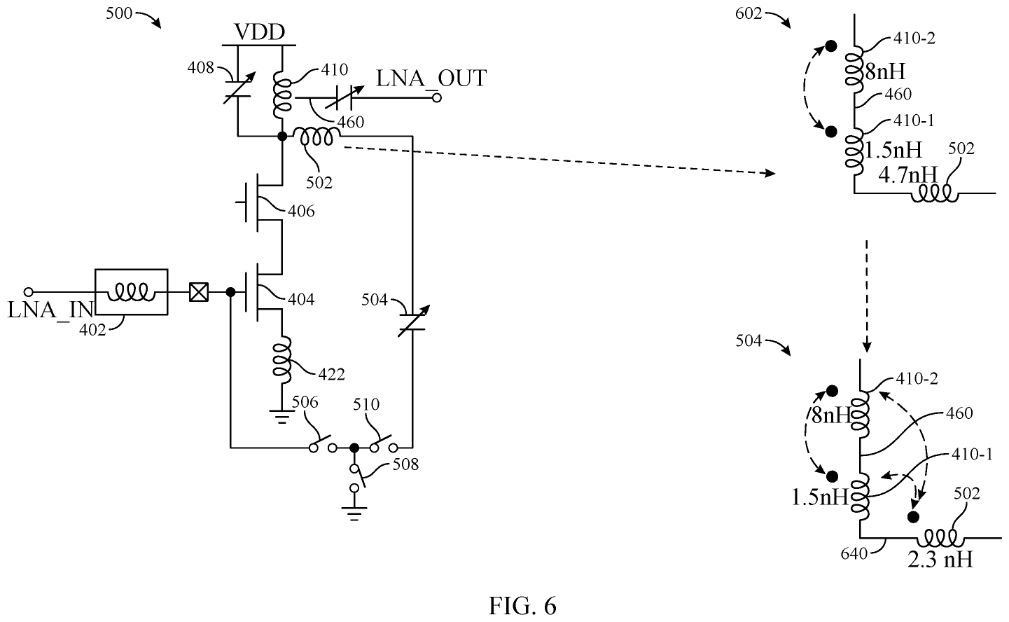

FIG. 6 illustrates an LNA 500 including a bypass inductive element magnetically coupled with an active inductive element, in accordance with certain aspects of the present disclosure. The diagram 602 shows inductive elements 410-1, 410-2, where inductive element 410-2 represents a portion of the inductive element 410 from the supply voltage node to the tap 460 and the inductive element 410-1 represents a portion of the inductive element 410 from tap 460 to the inductive element 502. In some aspects, the inductive elements 410-1, 410-2 may be magnetically coupled, as shown.

In some implementations, the inductive element 502 may be a standalone inductive element (e.g., not magnetically coupled to inductive element 410). In this case, the inductive element 410-1 may be a 8 nH inductive element, the inductive element 410-1 may be a 1.5 nH inductive element, and the inductive element 502 may be a 4.7 nH inductive element. In some aspects, as shown in diagram 604, the inductive element 502 may be magnetically coupled to each of inductive elements 410-1, 410-2, allowing the inductance of the inductive element 502 to be reduced from 4.7 nH to 2.3 nH, further decreasing the area consumption of the LNA. The inductive elements 502, 410-1, 410-2 may be implemented using a single inductive element structure having a first tap 460 between inductive elements 410-1, 410-2 and a second tap 640 between inductive elements 410-1, 502.

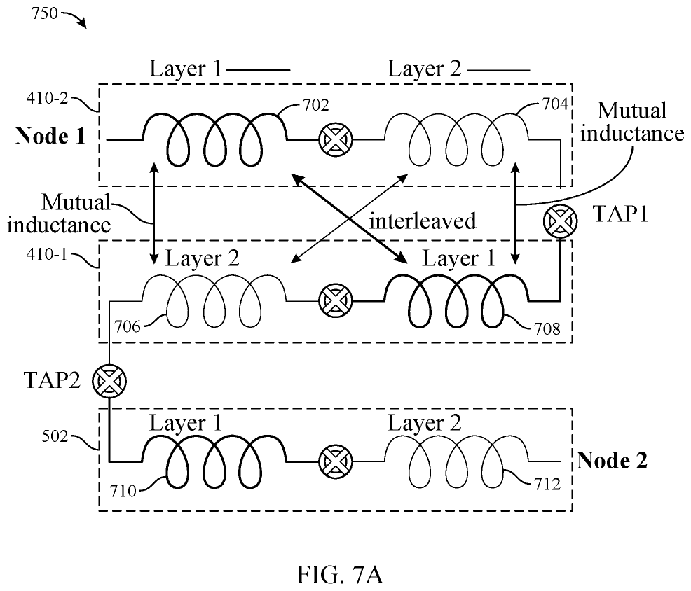

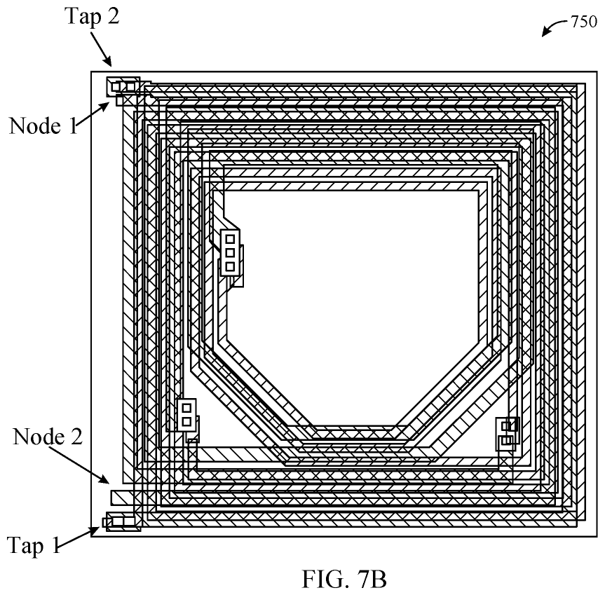

FIGS. 7A and 7B illustrate an inductive element structure 750 used to implement inductive elements 410, 502, in accordance with certain aspects of the present disclosure. As shown in FIG. 7A, the inductive element 410-2 may be coupled between a first node (labeled “Node 1”) and a first tap (e.g., tap 460, labeled “Tap 1” in FIG. 7A). The inductive element 410-2 may include an inductive element portion 702 implemented on a first layer (labeled “Layer 1”) of an integrated circuit (IC) and an inductive element portion 704 implemented on a second layer (labeled “Layer 2”) of the IC. The inductive element 410-1 may be coupled between Tap 1 and a second tap (e.g., tap 640, labeled “Tap 2” in FIG. 7A). The inductive element 410-1 may include an inductive element portion 708 implemented on Layer 1 and an inductive element portion 706 implemented on Layer 2. The inductive element 502 includes an inductive element portion 710 implemented on Layer 1 and an inductive element portion 712 implemented on Layer 2. As shown, the inductive element portions 702, 708 may be implemented using interleaved coils and inductive element portions 704, 706 may be implemented using interleaved coils. The inductive element portions 702, 706 may be magnetically coupled (e.g., have mutual inductance) and the inductive element portions 704, 708 may be magnetically coupled (e.g., have mutual inductance). As shown in FIG. 7B, the inductive elements 410, 502 may be implemented using an inductive element structure 750 across two layers of an integrated circuit (IC).

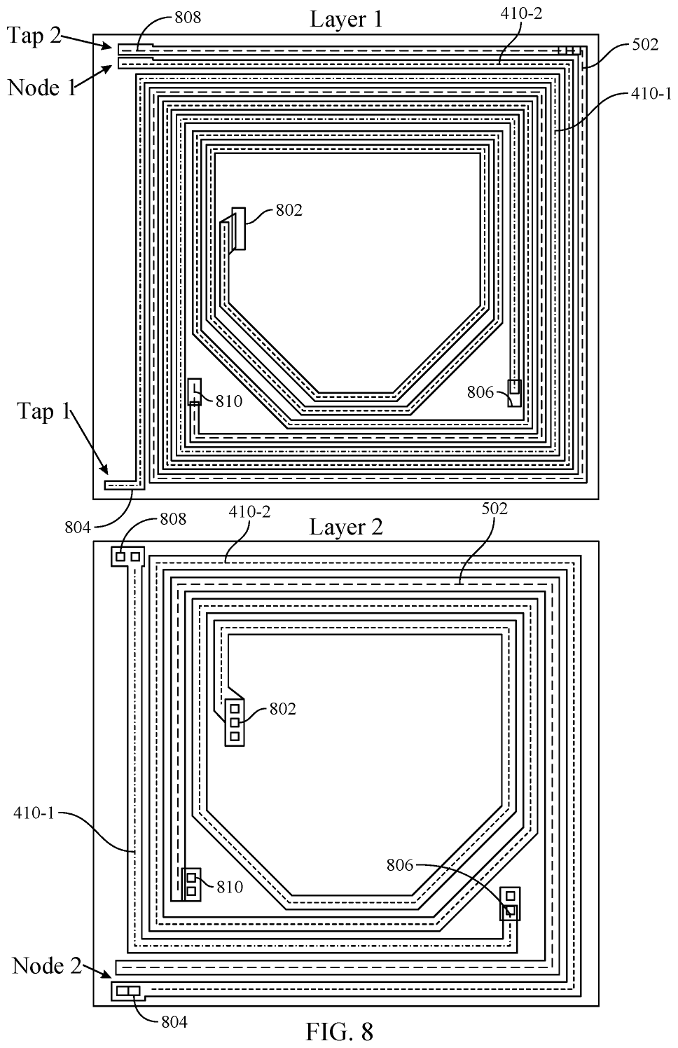

FIG. 8 illustrates the inductive element structure 750 implemented on two layers of an IC, in accordance with certain aspects of the present disclosure. As shown, the coil for inductive element 410-2 may begin from Node 1 on Layer 1 to via 802 from Layer 1 to Layer 2, implementing the inductive element portion 702 described with respect to FIG. 7A. The coil for inductive element 410-2 continues from via 802 on Layer 2 to via 804 (e.g., Tap 1) from Layer 2 to Layer 1, implementing the inductive element portion 704. The coil for inductive element 410-1 may begin from via 804 (Tap 1) on Layer 1 to via 806 from Layer 1 to Layer 2, implementing the inductive element portion 708 described with respect to FIG. 7A. The coil for inductive element 410-2 continues from via 806 on Layer 2 to via 808 (e.g., Tap 2) from Layer 2 to Layer 1, implementing the inductive element portion 706. The coil for inductive element 502 may begin from via 808 (Tap 2) on Layer 1 to via 810 from Layer 1 to Layer 2, implementing the inductive element portion 710 described with respect to FIG. 7A. The coil for inductive element 502 continues from via 810 on Layer 2 to Node 2, implementing the inductive element portion 712, as shown.

### Example Amplification Operations

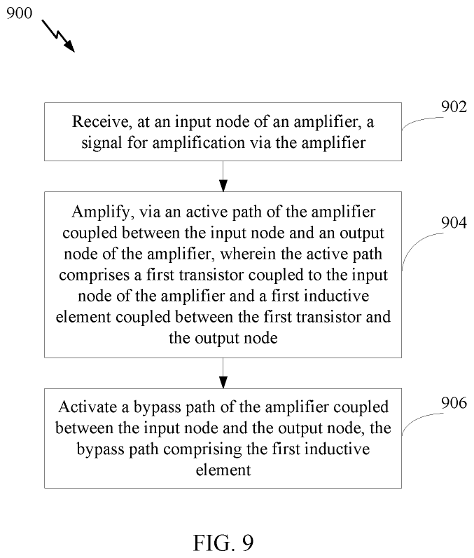

FIG. 9 is a flow diagram of example operations 900 for signal amplification, in accordance with certain aspects of the present disclosure. The operations 900 may be performed, for example, by an amplifier, such as the LNA 500.

At block 902, the amplifier may receive, at an input node (e.g., LNA_IN shown in FIG. 5) of an amplifier, a signal for amplification via the amplifier. At block 904, the amplifier amplifies, via an active path (e.g., path 450 of FIG. 5) of the amplifier coupled between the input node and an output node (e.g., LNA_OUT shown in FIG. 5) of the amplifier. The active path may include a first transistor (e.g., transistor 404) coupled to the input node of the amplifier and a first inductive element (e.g., inductive element 410-1 shown in FIG. 6) coupled between the first transistor and the output node. Amplifying the signal may include biasing a second transistor (e.g., transistor 406) coupled in cascode with the first transistor, where the first inductive element is coupled between the second transistor and the output node. In some aspects, the amplifier may adjust a capacitance of a capacitive element (e.g., capacitive element 412) of the active path coupled between the first inductive element and the output node. The amplifier may also include a second inductive element (e.g., inductive element 402) coupled between the input node and a gate of the first transistor.

At block 906, the amplifier activates a bypass path (e.g., path 520) of the amplifier coupled between the input node and the output node, the bypass path also including the first inductive element. The amplifier may include a second inductive element (e.g., inductive element 410-2) coupled to the first inductive element. A tap between the first inductive element and the second inductive element may be coupled to the output node. The amplifier may also include a capacitive element (e.g., capacitive element 408) coupled in parallel with a series combination of the first inductive element and the second inductive element. The capacitive element may be a variable capacitive element. The variable capacitive element, the first inductive element, and the second inductive element may form an impedance matching circuit for the active path. The amplifier may tune the impedance matching circuit by adjusting a capacitance of the variable capacitive element. In some aspects, the bypass path may include a third inductive element (e.g., inductive element 502 of FIG. 5) coupled to the first inductive element. The bypass path may include a capacitive element (e.g., capacitive element 504) coupled between a gate of the first transistor and the second inductive element. Activating the bypass path may include closing a first switch (e.g., switch 506) of the bypass path coupled between the gate of the first transistor and the capacitive element. In some cases, activating the bypass path may also include closing a second switch (e.g., switch 510) of the bypass path coupled between the first switch and the capacitive element and opening a third switch (e.g., switch 508) coupled between a reference potential node and a node (e.g., node 509) between the first switch and the second switch. The third inductive element may be magnetically coupled with each of the first inductive element and the second inductive element. In some aspects, a first portion of the first inductive element may be interleaved with a first portion of the second inductive element, and a second portion of the first inductive element may be interleaved with a second portion of the second inductive element. The first portion of the first inductive element and the first portion of the second inductive element may be on a first layer (e.g., Layer 1 shown in FIG. 8) of an integrated circuit (IC), and the second portion of the first inductive element and the second portion of the second inductive element are on a second layer (e.g., Layer 2 shown in FIG. 8) of the IC.

### Example Aspects

In addition to the various aspects described above, specific combinations of aspects are within the scope of the present disclosure, some of which are detailed below:

Aspect 1: An amplifier, comprising: an active path coupled between an input node of the amplifier and an output node of the amplifier, wherein the active path comprises a first transistor coupled to the input node of the amplifier and a first inductive element coupled between the first transistor and the output node; and a bypass path coupled between the input node of the amplifier and the output node of the amplifier, the bypass path comprising the first inductive element.

Aspect 2: The amplifier of Aspect 1, wherein the active path further comprises a second transistor coupled in cascode with the first transistor and wherein the first inductive element is coupled between the second transistor and the output node.

Aspect 3: The amplifier of Aspect 1 or 2, further comprising a second inductive element coupled to the first inductive element, wherein a tap between the first inductive element and the second inductive element is coupled to the output node.

Aspect 4: The amplifier of Aspect 3, further comprising a capacitive element coupled in parallel with a series combination of the first inductive element and the second inductive element.

Aspect 5: The amplifier of Aspect 4, wherein the capacitive element is a variable capacitive element and wherein the variable capacitive element, the first inductive element, and the second inductive element form an impedance matching circuit for the active path.

Aspect 6: The amplifier according to any of Aspects 3-5, wherein the bypass path further comprises a third inductive element coupled to the first inductive element.

Aspect 7: The amplifier of Aspect 6, wherein the bypass path further comprises a capacitive element coupled between a gate of the first transistor and the second inductive element.

Aspect 8: The amplifier of Aspect 7, wherein the bypass path further comprises a first switch coupled between the gate of the first transistor and the capacitive element.

Aspect 9: The amplifier of Aspect 8, wherein: the bypass path further comprises a second switch coupled between the first switch and the capacitive element; and the amplifier further comprises a third switch coupled between a reference potential node and a node between the first switch and the second switch.

Aspect 10: The amplifier according to any of Aspects 6-9, wherein the third inductive element is magnetically coupled with each of the first inductive element and the second inductive element.

Aspect 11: The amplifier of Aspect 10, wherein a first portion of the first inductive element is interleaved with a first portion of the second inductive element, and wherein a second portion of the first inductive element is interleaved with a second portion of the second inductive element.

Aspect 12: The amplifier of Aspect 11, wherein the first portion of the first inductive element and the first portion of the second inductive element are on a first layer of an integrated circuit (IC), and wherein the second portion of the first inductive element and the second portion of the second inductive element are on a second layer of the IC.

Aspect 13: The amplifier according to any of Aspects 1-12, wherein the active path comprises a capacitive element coupled between the first inductive element and the output node.

Aspect 14: The amplifier according to any of Aspects 1-13, further comprising a second inductive element coupled between the input node and a gate of the first transistor.

Aspect 15: A method for signal amplification, comprising: receiving, at an input node of an amplifier, a signal for amplification via the amplifier; amplifying, via an active path of the amplifier coupled between the input node and an output node of the amplifier, wherein the active path comprises a first transistor coupled to the input node of the amplifier and a first inductive element coupled between the first transistor and the output node; and activating a bypass path of the amplifier coupled between the input node and the output node, the bypass path comprising the first inductive element.

Aspect 16: The method of Aspect 15, wherein amplifying the signal comprises biasing a second transistor coupled in cascode with the first transistor and wherein the first inductive element is coupled between the second transistor and the output node.

Aspect 17: The method of Aspect 15 or 16, wherein the amplifier comprises a second inductive element coupled to the first inductive element and wherein a tap between the first inductive element and the second inductive element is coupled to the output node.

Aspect 18: The method of Aspect 17, wherein the amplifier further comprises a capacitive element coupled in parallel with a series combination of the first inductive element and the second inductive element.

Aspect 19: The method of Aspect 18, wherein the capacitive element is a variable capacitive element, wherein the variable capacitive element, the first inductive element, and the second inductive element form an impedance matching circuit for the active path, and wherein the method further comprises tuning the impedance matching circuit by adjusting a capacitance of the variable capacitive element.

Aspect 20: The method according to any of Aspects 17-19, wherein the bypass path further comprises a third inductive element coupled to the first inductive element.

Aspect 21: The method of Aspect 20, wherein the bypass path further comprises a capacitive element coupled between a gate of the first transistor and the second inductive element.

Aspect 22: The method of Aspect 21, wherein activating the bypass path comprises closing a first switch of the bypass path coupled between the gate of the first transistor and the capacitive element.

Aspect 23: The method of Aspect 22, wherein activating the bypass path further comprises: closing a second switch of the bypass path coupled between the first switch and the capacitive element; and opening a third switch coupled between a reference potential node and a node between the first switch and the second switch.

Aspect 24: The method according to any of Aspects 20-23, wherein the third inductive element is magnetically coupled with each of the first inductive element and the second inductive element.

Aspect 25: The method of Aspect 24, wherein a first portion of the first inductive element is interleaved with a first portion of the second inductive element, and wherein a second portion of the first inductive element is interleaved with a second portion of the second inductive element.

Aspect 26: The method of Aspect 25, wherein the first portion of the first inductive element and the first portion of the second inductive element are on a first layer of an integrated circuit (IC), and wherein the second portion of the first inductive element and the second portion of the second inductive element are on a second layer of the IC.

Aspect 27: The method according to any of Aspects 15-26, further comprising adjusting a capacitance of a capacitive element of the active path coupled between the first inductive element and the output node.

Aspect 28: The method according to any of Aspects 15-27, wherein the amplifier further comprises a second inductive element coupled between the input node and a gate of the first transistor.

Aspect 29: A wireless device, comprising: one or more antennas; and a low-noise amplifier (LNA) having an input node coupled to the one or more antennas, the LNA comprising: an active path coupled between the input node of the LNA and an output node of the LNA, wherein the active path comprises a transistor coupled to the input node and an inductive element coupled between the transistor and the output node; and a bypass path coupled between the input node and the output node, the bypass path comprising the inductive element.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An amplifier, comprising:
an active path coupled between an input node of the amplifier and an output node of the amplifier, wherein the active path comprises a first transistor coupled to the input node of the amplifier and a first inductive element coupled between the first transistor and the output node; and
a bypass path coupled between the input node of the amplifier and the output node of the amplifier, the bypass path comprising the first inductive element.

2. The amplifier of claim 1, wherein the active path further comprises a second transistor coupled in cascode with the first transistor and wherein the first inductive element is coupled between the second transistor and the output node.

3. The amplifier of claim 1, further comprising a second inductive element coupled to the first inductive element, wherein a tap between the first inductive element and the second inductive element is coupled to the output node.

4. The amplifier of claim 3, further comprising a capacitive element coupled in parallel with a series combination of the first inductive element and the second inductive element.

5. The amplifier of claim 4, wherein the capacitive element is a variable capacitive element and wherein the variable capacitive element, the first inductive element, and the second inductive element form an impedance matching circuit for the active path.

6. The amplifier of claim 3, wherein the bypass path further comprises a third inductive element coupled to the first inductive element.

7. The amplifier of claim 6, wherein the bypass path further comprises a capacitive element coupled between a gate of the first transistor and the second inductive element.

8. The amplifier of claim 7, wherein the bypass path further comprises a first switch coupled between the gate of the first transistor and the capacitive element.

9. The amplifier of claim 8, wherein:
the bypass path further comprises a second switch coupled between the first switch and the capacitive element; and
the amplifier further comprises a third switch coupled between a reference potential node and a node between the first switch and the second switch.

10. The amplifier of claim 6, wherein the third inductive element is magnetically coupled with each of the first inductive element and the second inductive element.

11. The amplifier of claim 10, wherein a first portion of the first inductive element is interleaved with a first portion of the second inductive element, and wherein a second portion of the first inductive element is interleaved with a second portion of the second inductive element.

12. The amplifier of claim 11, wherein the first portion of the first inductive element and the first portion of the second inductive element are on a first layer of an integrated circuit (IC), and wherein the second portion of the first inductive element and the second portion of the second inductive element are on a second layer of the IC.

13. The amplifier of claim 1, wherein the active path comprises a capacitive element coupled between the first inductive element and the output node.

14. The amplifier of claim 1, further comprising a second inductive element coupled between the input node and a gate of the first transistor.

15. A method for signal amplification, comprising:
receiving, at an input node of an amplifier, a signal for amplification via the amplifier;
amplifying, via an active path of the amplifier coupled between the input node and an output node of the amplifier, wherein the active path comprises a first transistor coupled to the input node of the amplifier and a first inductive element coupled between the first transistor and the output node; and
activating a bypass path of the amplifier coupled between the input node and the output node, the bypass path comprising the first inductive element.

16. The method of claim 15, wherein amplifying the signal comprises biasing a second transistor coupled in cascode with the first transistor and wherein the first inductive element is coupled between the second transistor and the output node.

17. The method of claim 15, wherein the amplifier comprises a second inductive element coupled to the first inductive element and wherein a tap between the first inductive element and the second inductive element is coupled to the output node.

18. The method of claim 17, wherein the amplifier further comprises a capacitive element coupled in parallel with a series combination of the first inductive element and the second inductive element.

19. The method of claim 18, wherein the capacitive element is a variable capacitive element, wherein the variable capacitive element, the first inductive element, and the second inductive element form an impedance matching circuit for the active path, and wherein the method further comprises tuning the impedance matching circuit by adjusting a capacitance of the variable capacitive element.

20. The method of claim 17, wherein the bypass path further comprises a third inductive element coupled to the first inductive element.

21. The method of claim 20, wherein the bypass path further comprises a capacitive element coupled between a gate of the first transistor and the second inductive element.

22. The method of claim 21, wherein activating the bypass path comprises closing a first switch of the bypass path coupled between the gate of the first transistor and the capacitive element.

23. The method of claim 22, wherein activating the bypass path further comprises:
closing a second switch of the bypass path coupled between the first switch and the capacitive element; and
opening a third switch coupled between a reference potential node and a node between the first switch and the second switch.

24. The method of claim 20, wherein the third inductive element is magnetically coupled with each of the first inductive element and the second inductive element.

25. The method of claim 24, wherein a first portion of the first inductive element is interleaved with a first portion of the second inductive element, and wherein a second portion of the first inductive element is interleaved with a second portion of the second inductive element.

26. The method of claim 25, wherein the first portion of the first inductive element and the first portion of the second inductive element are on a first layer of an integrated circuit (IC), and wherein the second portion of the first inductive element and the second portion of the second inductive element are on a second layer of the IC.

27. The method of claim 15, further comprising adjusting a capacitance of a capacitive element of the active path coupled between the first inductive element and the output node.

28. The method of claim 15, wherein the amplifier further comprises a second inductive element coupled between the input node and a gate of the first transistor.

29. A wireless device, comprising:
one or more antennas; and
a low-noise amplifier (LNA) having an input node coupled to the one or more antennas, the LNA comprising:
an active path coupled between the input node of the LNA and an output node of the LNA, wherein the active path comprises a transistor coupled to the input node and an inductive element coupled between the transistor and the output node; and
a bypass path coupled between the input node and the output node, the bypass path comprising the inductive element.
